(19) United States
(12) Patent Application Publication
(10) Pub. No.: US 2010/0029193 A1
(43) Pub. Date: Feb. 4, 2010

(54) METHOD FOR PREVENTING AIR RECIRCULATION AND OVERSUPPLY IN DATA CENTERS

(75) Inventors: Steven John AHLADAS, Highland, NY (US); Roger R. SCHMIDT, Poughkeepsie, NY (US); Gerard Vincent WEBER, JR., Saugerties, NY (US)

Correspondence Address: McGinn Intellectual Property Law Group, PLLC, 8321 Old Courthouse Road, Suite 200, Vienna, VA, 22182-3817, US

(73) Assignee: INTERNATIONAL BUSINESS MACHINES CORPORATION, Armonk, NY (US)

(21) Appl. No.: 12/184,053

(22) Filed: Jul. 31, 2008

(51) Int. Cl. H05K 5/00

(52) U.S. Cl. 454/184

(57) ABSTRACT

A method for preventing air recirculation in a data center is provided. The method includes specifying a target temperature of IT equipment and a flow volume of cold air entering an IT equipment rack, detecting an under-floor air temperature using a first temperature sensor provided in an under-floor plenum positioned adjacent to a cooling mechanism, detecting an IT equipment inlet temperature using a second temperature sensor positioned adjacent to a top portion of an IT equipment rack including the IT equipment, the IT equipment rack formed on a floor surface of the data center, the floor surface separating the under-floor plenum from the IT equipment rack, removing warm air exhausted from the IT equipment rack into a CRAC, chilling the warm air removed into the CRAC, the warm air being transformed by the CRAC into the cold air, exhausting the cold air from the CRAC to the under-floor plenum, controlling the cooling mechanism to regulate a cooling mechanism flow volume of the cold air in the under-floor plenum to the IT equipment rack such that the target temperature of IT equipment approximates the IT equipment inlet temperature and the cooling mechanism flow volume of the cold air equals the flow volume of the cold air entering into the IT equipment rack, and drawing the cold air into the IT equipment rack, the cold air being transformed by heat generated by the IT equipment into the warm air.

### BACKGROUND OF THE INVENTION

1. Field of the Invention

The present invention generally relates to a method for preventing air recirculation in data centers, and, more specifically, a method thereof in which no exhaust air from an information technology (IT) equipment rack is recirculated into an inlet of the IT equipment rack and chilled air oversupply to the IT equipment rack is prevented.

2. Description of the Related Art

A conventional method of cooling a data center involves placing IT equipment of the data center on a ‘raised floor’ system. This allows for the delivery of cool air to the IT equipment through an area provided under the raised floor of the data center. The raised floor is a system of standard sized panels that are placed on pedestals and serve to create a secondary floor, typically 12″-24″ above a slab of the data center.

Computer Room Air Conditioners (CRACs) are configured to take air that is warm from the room, chill the warm air, and force the resultant chilled air into an under-floor plenum between the slab and the raised floor. One or more perforated tiles are placed by an air inlet located near the IT equipment. This air inlet allows the cool air to be delivered to the equipment from the under-floor plenum.

However, in today's high density data centers, supplying the proper amount of chilled air to the IT equipment inhabiting the high density data center can be difficult. A high density server requires substantial amounts of chilled air. Air flow provided by a normal environment is unlikely to be able provide the high density server with a requisite amount of air flow needed for effective cooling. Inevitably, if enough flow is not provided from the under-floor plenum, the warm areas of the data center overwhelm the cold areas, subsequently reducing the efficiency of the cooling system. In this condition, the IT equipment is susceptible to overheating.

Furthermore, a volume of air provided to cool the server may be variable, due to speed control of air movers in the IT equipment. Even if a maximum amount of static air flow is supplied to the server, if the server is not operating at full flow, the chilled air will not be used by the IT equipment and will mix with warm air in the room which will then degrade the overall efficiency of the data center chilling system. In fact, this configuration sends a significant amount of chilled air directly back to the CRACs, bypassing the cooling of the IT equipment altogether.

A ‘smart data center’ has been proposed where temperatures are monitored within the data center and air flow is adjusted to assure the inlet temperature of the equipment is met. This solution uses a control damper on the raised floor tile. The raised floor tile can be opened or closed until a desired temperature of the IT equipment is met.

In this ‘smart data center’, however, there is no use of an under-floor air temperature to control the temperature of the IT equipment. This is important because the inlet temperatures of the IT rack equipment will only be uniform when the cool air supplied by the CRACs at the inlet to the rack equals or exceeds the air flow rate of the air movers in the rack. When the air flow is not sufficient, recirculation of warm air from the rack outlet will return to the inlet, typically over the top of the rack unit. The result is a gradient in air temperature, with the equipment close to the floor having cool unmixed air from the CRACs and the equipment on top having the warmest air due to the recirculation. These gradients can easily achieve 10 degrees C.

Due to the wide operating range of IT equipment, this recirculation causes many racks to be installed utilizing a wide range of inlet temperatures. CRACs will regulate only based on the warm air that is returned. Thus, when recirculation occurs, the CRACs cannot properly regulate the amount of chilled air being delivered.

The conventional method of cooling employs the algorithm f′=K₁(tₑ−tₛ). where f′ is the air flow volume from a cooling mechanism (e.g., active floor tile, servo controlled damper, or adjustable forced air) that is controlled by an error term whose value is proportional to the difference of a set point and measured value, K₁ is a gain constant, tₑ is the inlet temperature of the IT equipment, and tₛ is a specified target temperature of the IT equipment.

Conventionally, the air located in the under-floor plenum is much colder than tₛ. The value of tₑ is determined by sensors located around the inlet temperature of the IT equipment. tₑ is used by the algorithm to determine how much cold air needs to be supplied from the CRACs into the under-floor plenum. However, the conventional method of cooling can lead to inflection points in the above algorithm. Specifically, the conventional method of cooling allows for cold underfloor air to mix with recirculated air exhausted from the IT equipment to meet tₛ.

The influence of the recirculated air in the above algorithm leads to f′<f where f is the air flow volume into the IT equipment, which is not a controllable parameter, as the equipment itself controls this value. Thus, non-uniform inlet air, which is a mix of cold underfloor air and the recirculated air, is provided to cool the IT equipment. The conventional method, which allows recirculated air to enter the IT equipment rack and decouples the air temperature of the under-floor plenum from the aforementioned algorithm, makes setting the air temperature of the under-floor plenum much more difficult.

The optimal control algorithm would, therefore, not only provide for inlet temperatures that are specified as optimal or accepted for the IT equipment to be cooled, but also provide for uniform temperatures at the rack inlets, allowing for all equipment to operate in the center of their design point, and provide control for air temperature of the under-floor plenum. The CRACs are the only ‘input’ to the ‘plant’ of the entire data center temperatures. By forming local temperature regulation loops based on server inlet temperatures as is done in conventional cooling systems, the ability of the CRACs to deliver the correct amount of chilled air is inhibited.

### SUMMARY OF THE INVENTION

In view of the foregoing and other exemplary problems, drawbacks, and disadvantages of the conventional methods and structures, an exemplar object of the present invention is to provide a method for preventing air recirculation and chilled air oversupply to IT equipment in data centers by providing a uniform temperature at an inlet of an IT equipment rack.

An exemplary embodiment of the present invention includes a method for preventing air recirculation or oversupply in a data center, including specifying a target temperature of IT equipment and a flow volume of cold air entering an IT equipment rack, detecting an under-floor air temperature using a first temperature sensor provided in an under-floor plenum positioned adjacent to a cooling mechanism, detecting an IT equipment inlet temperature using a second temperature sensor positioned adjacent to a top portion of an IT equipment rack including the IT equipment, the IT equipment rack formed on a floor surface of the data center, the floor surface separating the under-floor plenum from the IT equipment rack, removing warm air exhausted from the IT equipment rack into a CRAC, chilling the warm air removed into the CRAC, the warm air being transformed by the CRAC into the cold air, exhausting the cold air from the CRAC to the under-floor plenum, controlling the cooling mechanism to regulate a cooling mechanism flow volume of the cold air in the under-floor plenum to the IT equipment rack such that the target temperature of IT equipment approximates the IT equipment inlet temperature and the cooling mechanism flow volume of the cold air equals the flow volume of the cold air entering into the IT equipment rack, and drawing the cold air into the IT equipment rack, the cold air being transformed by heat generated by the IT equipment into the warm air.

The warm air exhausted from the IT equipment rack is prevented from recirculating into the IT equipment rack, The cooling mechanism includes one of active floor tile, servo controlled damper, and adjustable forced air. An entirety of the warm air exhausted from the IT equipment rack is removed into the CRAC.

According to the exemplary embodiment of the present invention, the temperature of the air at the input of the IT equipment rack is the same as the temperature of the air underneath the cooling mechanism. In addition, the flow volume of the chilled air controlled by the cooling mechanism is the same as the flow volume of the chilled air entering the IT equipment rack. Thus, no air is recirculated from the warm air exhaust of the IT equipment rack and a temperature of the IT equipment is properly regulated. This allows the decoupling of the airflow inlet of the IT equipment with respect to the temperature regulation of the data center.

### BRIEF DESCRIPTION OF THE DRAWINGS

The foregoing and other exemplary purposes, aspects and advantages will be better understood from the following detailed description of an exemplary embodiment of the invention with reference to the drawings, in which:

FIG. 1 illustrates an exemplary embodiment of a system for preventing air recirculation in data centers of the present invention; and

FIG. 2 illustrates an exemplary embodiment of a method for preventing air recirculation in data centers of the present invention.

### DETAILED DESCRIPTION OF EXEMPLARY EMBODIMENTS OF THE INVENTION

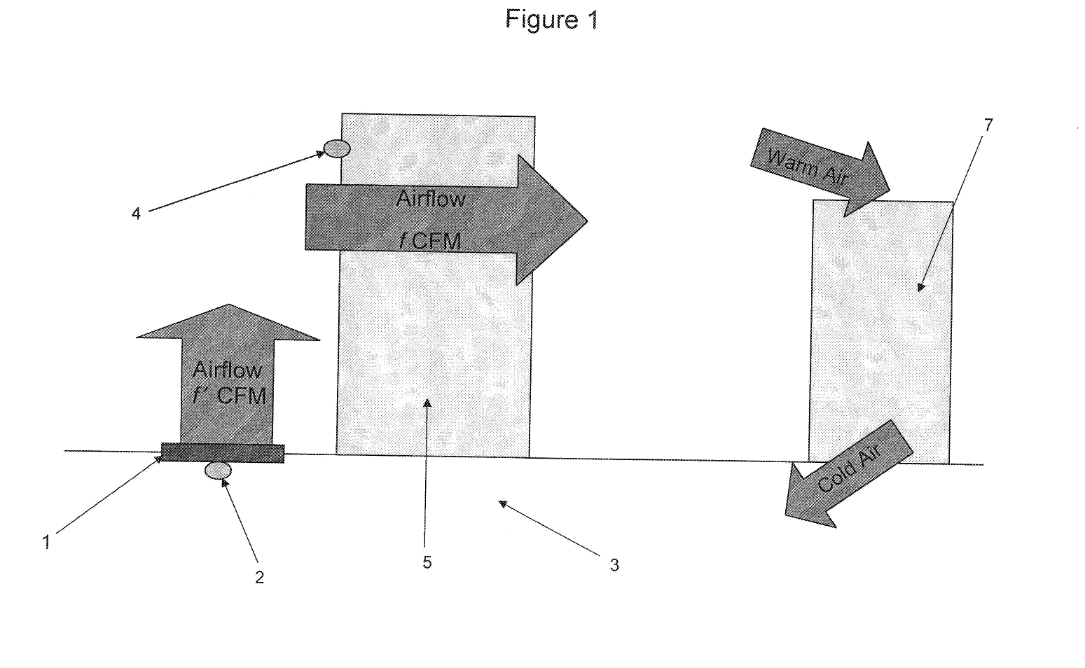

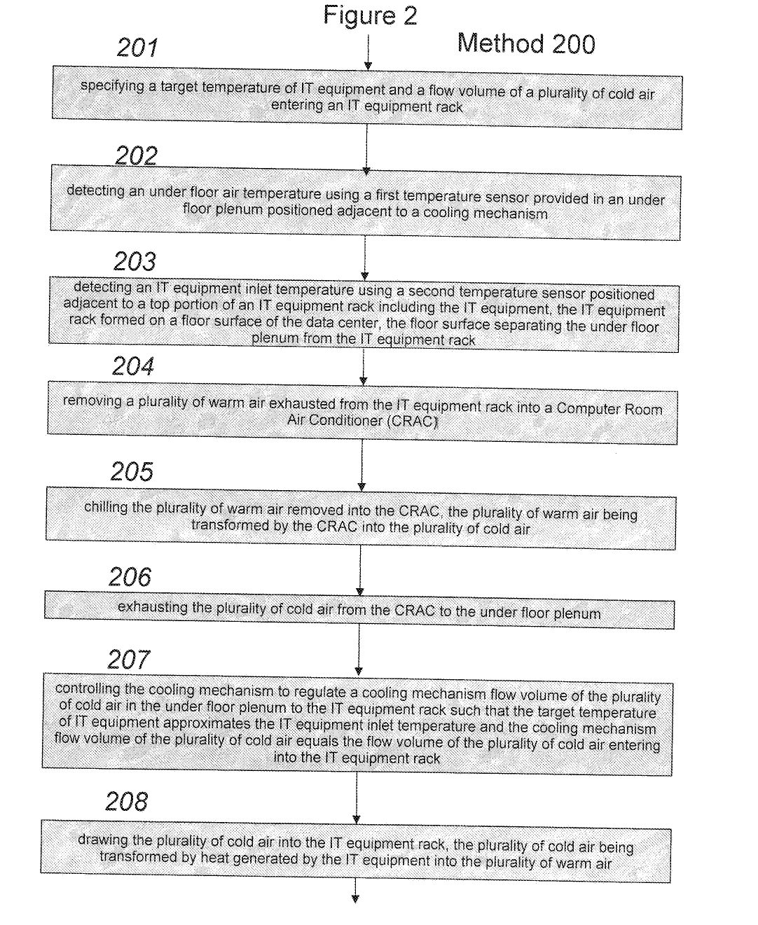

Referring now to the drawings, and more particularly to FIGS. 1 and 2, there are shown exemplary embodiments of the structures and method according to the present invention.

An exemplary embodiment of the present invention, as shown in FIG. 1, includes a cooling mechanism 1. The cooling mechanism may be one of an active floor tiling, movable servo controlled dampers, and integrated air movers producing adjustable forced air. In addition, an under-floor temperature sensor 2 is provided underneath and adjacent to the cooling mechanism 1. The under-floor temperature sensor 2 is provided to detect the temperature in the under-floor plenum 3. Also, an IT equipment inlet temperature sensor 4 is provided to detect an IT equipment inlet temperature near an upper portion of an IT equipment rack 5. The IT equipment to be cooled is housed inside the IT equipment rack 5. In addition, a CRAC 7 is provided for taking in an exhaust of warm air from the IT equipment rack 5 and transforming the exhaust into cold or chilled air to be forced into the under-floor plenum 3.

The temperature of the IT equipment inlet is detected to regulate the temperature near the top of the rack to approximate the temperature of the under-floor plenum 3, not the input specification of the equipment as in the conventional cooling method. This exemplary feature of the exemplary embodiment of the present invention prevents the recirculation of warm air to the inlet of the IT equipment rack 5 and allows all the warm air the ability to return to the CRAC 7, where temperarture is properly regulated. Thus, all hot air is returned to the CRAC 7, allowing for more efficient cooling operation and non ambiguous control laws. By preventing recirculation, the inlet temperature of the server will also be more uniform.

The exemplary embodiment of the present invention employs an algorithm f′=K₂(tₑ−tᵤ), where f′ is the air flow volume from a cooling mechanism (e.g., active floor tile, servo controlled damper, or adjustable forced air) that is controlled by an error term whose value is proportional to the difference of a set point and measured value, K₂ is a gain constant, tₑ is the inlet temperature of the IT equipment, and tᵤ is the temperature of the under-floor plenum 3. The goal of the algorithm of the exemplary embodiment of the present invention is to force f=f′, where f is the air flow volume into the IT equipment, which is not a controllable parameter, as the equipment itself controls this value.

This algorithm of the exemplary embodiment of the present invention assures that no recirculation of warm air will occur. In doing so, it allows the CRAC temperature setpoint tₛ to be set directly such that tₛ=tᵤ. In addition, a local regulation done by the cooling mechanism 1 assures that tₑ approximates tᵤ. Thus, the recirculated air is effectively removed as an unacknowledged error variable in the control process.

FIG. 2 illustrates an exemplary embodiment of a 200 method for preventing air recirculation in data centers of the present invention. The method 200 includes specifying (201) a target temperature of IT equipment and a flow volume of cold air entering an IT equipment rack, detecting (202) an under-floor air temperature using a first temperature sensor provided in an under-floor plenum positioned adjacent to a cooling mechanism, detecting (203) an IT equipment inlet temperature using a second temperature sensor positioned adjacent to a top portion of an IT equipment rack including the IT equipment, the IT equipment rack formed on a floor surface of the data center, the floor surface separating the under-floor plenum from the IT equipment rack, removing (204) warm air exhausted from the IT equipment rack into a CRAC, chilling (205) the warm air removed into the CRAC the warm air being transformed by the CRAC into the cold air. exhausting (206) the cold air from the CRAC to the under-floor plenum, controlling (207) the cooling mechanism to regulate a cooling mechanism flow volume of the cold air in the under-floor plenum to the IT equipment rack such that the target temperature of IT equipment approximates the IT equipment inlet temperature and the cooling mechanism flow volume of the cold air equals the flow volume of the cold air entering into the IT equipment rack, and drawing (208) the cold air into the IT equipment rack, the: cold air being transformed by heat generated by the IT equipment into the warm air.

The control laws presented in the exemplary embodiment of the present invention are simplified to show proportional control, but the base concept of this invention applies to derivative, integral, and digital control algorithms as well.

While the invention has been described in terms of several exemplary embodiments, those skilled in the art will recognize that the invention can be practiced with modification within the spirit and scope of the appended claims. Further, it is noted that Applicant's intent is to encompass equivalents of all claim elements, even if amended later during prosecution.

What is claimed is:

1. A method for preventing air recirculation or oversupply in a data center, comprising:
specifying a target temperature of information technology (IT) equipment and a flow volume of cold air entering an IT equipment rack;
detecting an under-floor air temperature using a first temperature sensor provided in an under-floor plenum positioned adjacent to a cooling mechanism;
detecting an IT equipment inlet temperature using a second temperature sensor positioned adjacent to a top portion of an IT equipment rack comprising said IT equipment, said IT equipment rack formed on a floor surface of said data center, said floor surface separating said under-floor plenum from said IT equipment rack;
removing warm air exhausted from said IT equipment rack into a Computer Room Air Conditioner (CRAC);
chilling said warm air removed into said CRAC, said warm air being transformed by said CRAC into said cold air;
exhausting the cold air from the CRAC to the under-floor plenum;
controlling said cooling mechanism to regulate a cooling mechanism flow volume of said cold air in said under-floor plenum to said IT equipment rack such that said target temperature of IT equipment approximates said IT equipment inlet temperature and said cooling mechanism flow volume of said cold air equals said flow volume of said cold air entering into said IT equipment rack; and
drawing said cold air into said IT equipment rack, said cold air being transformed by heat generated by said IT equipment into said warm air,
wherein said warm air exhausted from said IT equipment rack is prevented from recirculating into said IT equipment rack,
wherein said cooling mechanism comprises one of active floor tile, servo controlled damper, and adjustable forced air,
wherein an entirety of said warm air exhausted from said IT equipment rack is removed into said CRAC.
